(19) United States
(12) Patent Application Publication
(10) Pub. No.: US 2021/0265320 A1
(43) Pub. Date: Aug. 26, 2021

(54) LIGHT-EMITTING DIODE PACKAGE STRUCTURE AND METHOD FOR MANUFACTURING SAME

(71) Applicant: ADVANCED OPTOELECTRONIC TECHNOLOGY, INC., Hsinchu Hsien (TW)

(72) Inventors: CHENG-KUO FENG, Hsinchu (TW); SHIUE-LUNG CHEN, Hsinchu (TW)

(21) Appl. No.: 16/854,007

(22) Filed: Apr. 21, 2020

(30) Foreign Application Priority Data
Feb. 26, 2020 (CN) 202010120315.5

(51) Int. Cl. H01L 25/075; H01L 33/36; H01L 33/62; H01L 33/58; H01L 33/50; H01L 33/00

(52) U.S. Cl. CPC H01L 25/0753; H01L 33/36; H01L 33/62; H01L 33/58; H01L 2933/0058; H01L 33/0093; H01L 2933/0066; H01L 2933/0041; H01L 33/505

(57) ABSTRACT

A light-emitting diode package structure includes an array substrate, a plurality of light-emitting diodes arranged in an array on the array substrate, and a retaining wall arranged on the array substrate. The retaining wall isolates each of the plurality of light-emitting diodes.

### FIELD

The subject matter herein generally relates to a light-emitting diode package structure and a method for manufacturing the light-emitting diode package structure.

### BACKGROUND

A micro-light-emitting diode (LED) unit is generally less than 50 microns in size. The micro-LED unit has the advantages of high efficiency, high brightness, and small size. However, because a unit pitch in a micro-LED array on a chip is very small, light fields between adjacent LED units overlap, which makes it difficult to exhibit a point light emitting effect and causes low display definition.

### BRIEF DESCRIPTION OF THE DRAWINGS

Implementations of the present disclosure will now be described, by way of embodiments, with reference to the attached figures.

FIG. 1 is a schematic cross-sectional view of an array substrate of a light-emitting diode package structure.

FIG. 2 is a schematic cross-sectional view of a carrier substrate of the light-emitting diode package structure.

FIG. 3 is a schematic cross-sectional view illustrating an alignment process of the array substrate shown in FIG. 1 and the carrier substrate shown in FIG. 2.

FIG. 4 is a schematic cross-sectional view of the array substrate shown in FIG. 1 pressed to the carrier substrate shown in FIG. 2.

FIG. 5 is a schematic cross-sectional view of the carrier substrate peeled off from the structure shown in FIG. 4.

FIG. 6 is a schematic cross-sectional view of the array substrate shown in FIG. 5.

FIG. 7 is a schematic top plan view of the array substrate shown in FIG. 6.

FIG. 8 is a schematic cross-sectional view of the array substrate in FIG. 6 with a retaining wall.

FIG. 9 is a schematic top plan view of the array substrate shown in FIG. 8.

FIG. 10 is a schematic cross-sectional view of the array substrate with a color conversion gel and a diffusion gel.

FIG. 11 is a schematic cross-sectional view of the array substrate with a transparent protective layer.

FIG. 12 is a schematic flowchart of a method for manufacturing the light-emitting diode package structure.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

FIG. 12 is a flowchart of an embodiment of a method for manufacturing a light-emitting diode package structure.

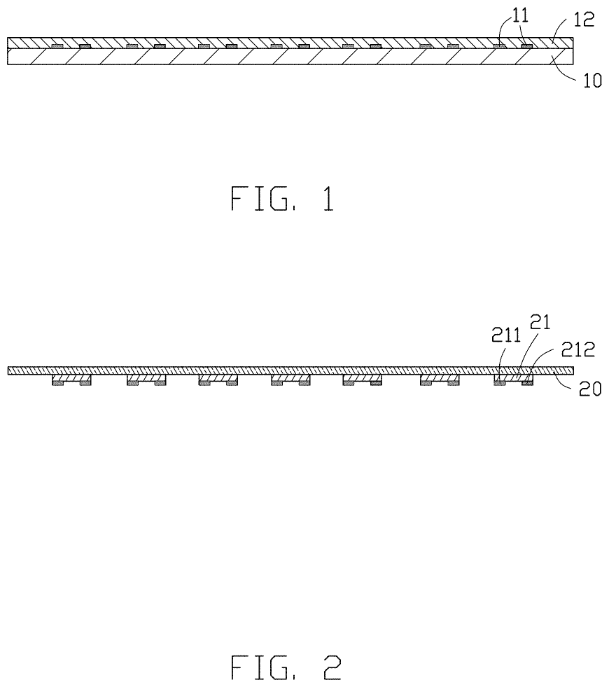

Block S1: As shown in FIG. 1, a plurality of connection pads 11 is formed in an array on an array substrate 10, and an anisotropic conductive adhesive film 12 is covered on a side of the array substrate 10 on which the plurality of connection pads 11 is formed.

The array substrate 10 may be made of a light-transmissive material, such as glass, quartz, plastic, rubber, fiberglass, or other polymer materials. The array substrate 10 may also be made of an opaque material, such as a metal-glass fiber composite board and a metal-ceramic composite board.

The anisotropic conductive adhesive film 12 includes a resin matrix and conductive particles. In one embodiment, a thickness of the anisotropic conductive adhesive film 12 is 10-20 microns, and a particle diameter of the conductive particles in the anisotropic conductive adhesive film 12 is 3-10 microns.

Block S2: As shown in FIG. 2, a plurality of light-emitting diodes 21 is formed in an array on a carrier substrate 20. Each of the light-emitting diodes 21 includes a first electrode 211 and a second electrode 212. The first electrodes 211 and the second electrodes 212 are correspondingly connected to the connection pads 11 on the array substrate 10.

The light-emitting diode 21 is a micro light-emitting diode or a sub-millimeter light-emitting diode.

The carrier substrate 20 may be a wafer made of a light-transmissive or non-light-transmissive material, such as sapphire, gallium arsenide (GaAs), or silicon carbide (SiC).

The order of block S1 and block S2 may be reversed or performed simultaneously.

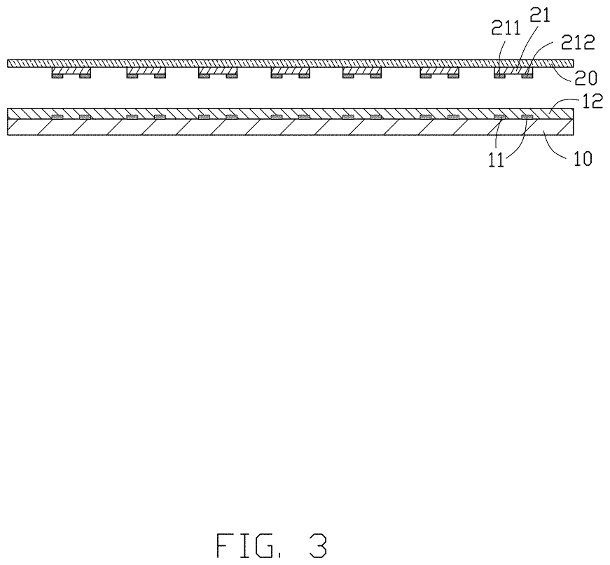

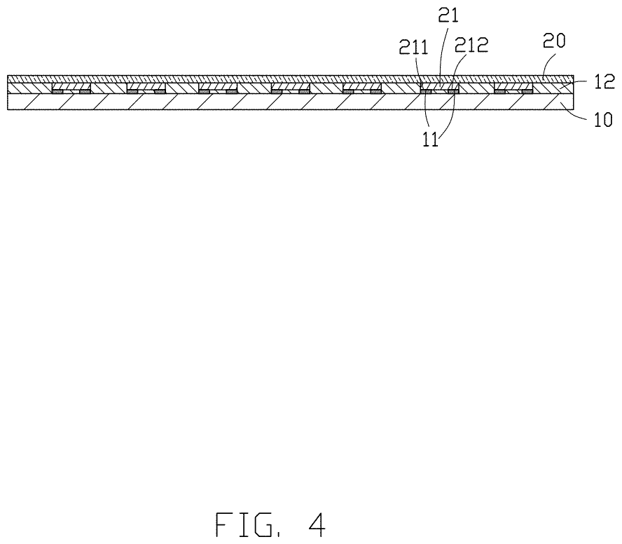

Block S3: As shown in FIG. 3 and FIG. 4, the connection pads 11 on the array substrate 10 are aligned with the first electrodes 211 and the second electrodes 212 on the carrier substrate 20 and then pressed together.

In one embodiment, a low-temperature pre-pressing method and a high-temperature pressing method are used to make the anisotropic conductive adhesive film 12 reactively bond by thermosetting between the connection pads 11 and the first electrodes 211 and the second electrodes 212. The anisotropic conductive adhesive film 12 after thermosetting has high adhesion and moisture-proof functions. In addition, the anisotropic conductive adhesive film 12 after thermosetting has conductivity in a direction perpendicular to the array substrate 10 and does not have conductivity in a direction parallel to the array substrate 10.

In one embodiment, during the alignment process, the connection pads 11 on the array substrate 10 may be aligned with the first electrodes 211 and the second electrode 212 on the carrier substrate 20 by an alignment device, such as a CCD camera.

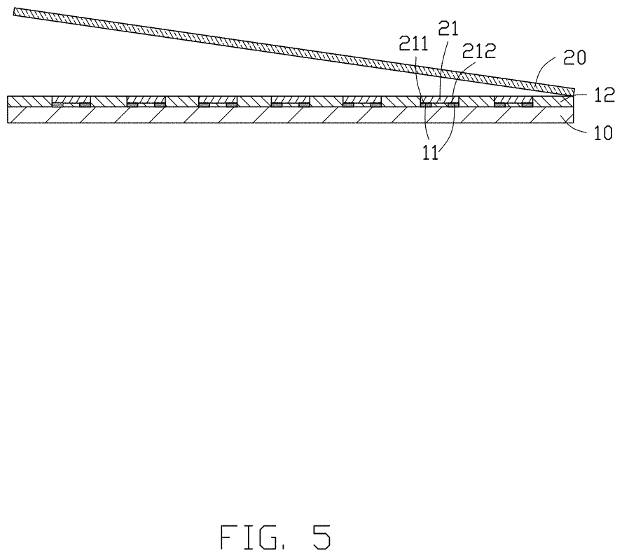

Block S4: As shown in FIG. 5, the carrier substrate 20 is peeled off.

In one embodiment, the carrier substrate 20 is peeled off by a laser peeling technique. Specifically, a connection interface between the light-emitting diodes 21 and the carrier substrate 20 is decomposed by laser energy, so that the light-emitting diodes 21 are separated from the carrier substrate 20.

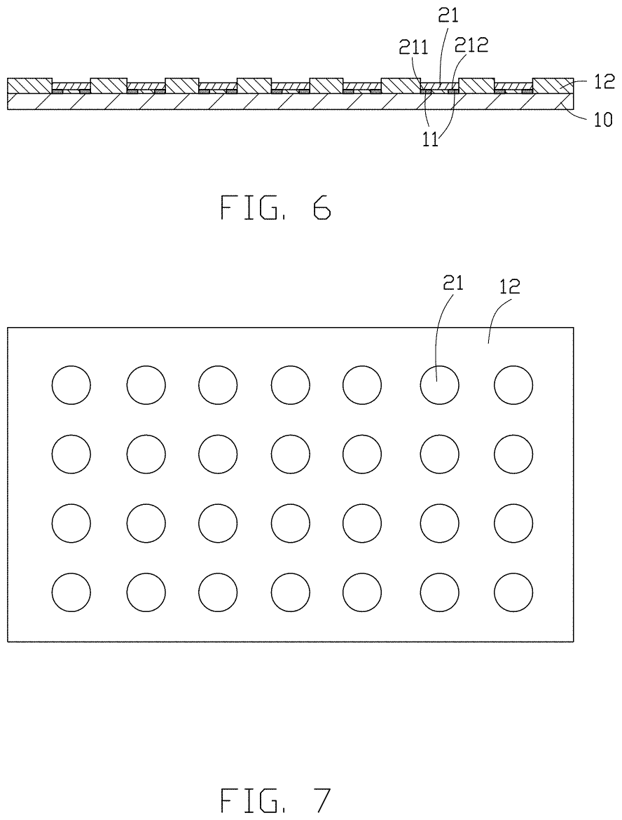

Referring to FIG. 6 and FIG. 7, since the carrier substrate 20 is peeled off, a portion of the anisotropic conductive adhesive film 12 surrounding each of the light-emitting diodes 21 will be pulled away from the array substrate 10 in a direction perpendicular to the array substrate 10 so that the light-emitting diodes 21 are recessed relative to the anisotropic conductive adhesive film 12.

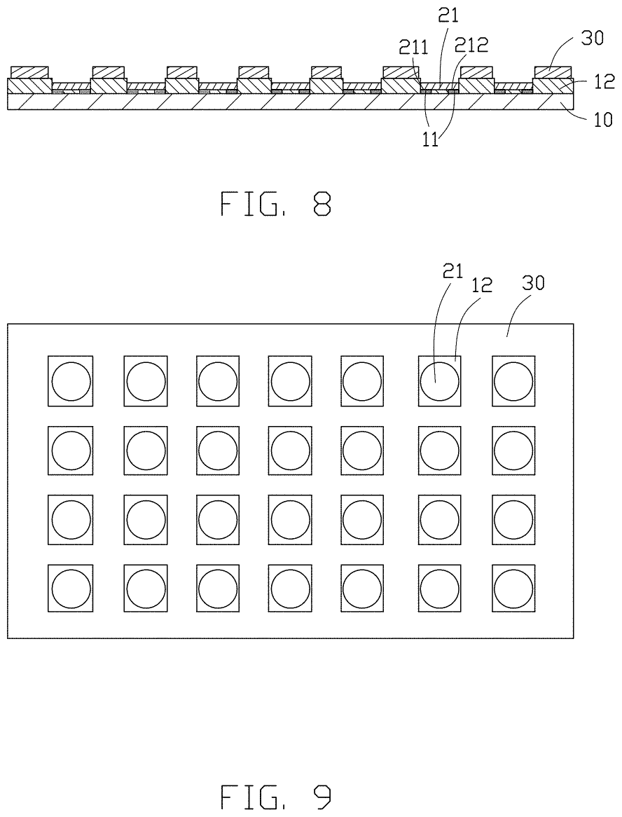

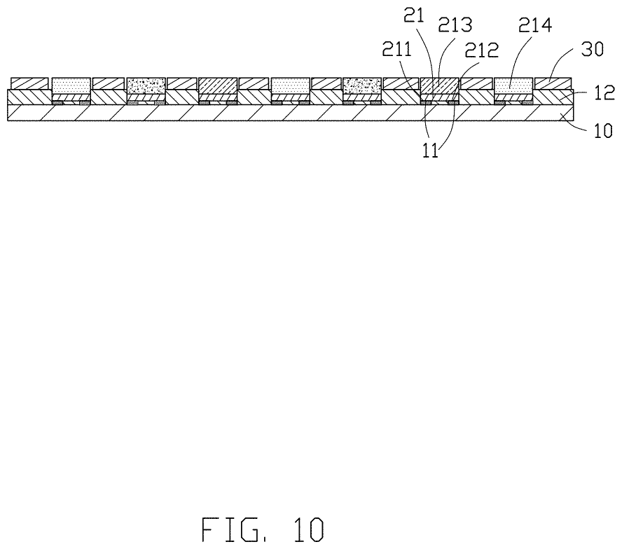

Block S5: As shown in FIG. 8 and FIG. 9, a retaining wall 30 is formed around each of the light-emitting diodes 21.

Specifically, the retaining wall 30 is formed on the anisotropic conductive adhesive film 12 surrounding each of the light-emitting diodes 21.

The retaining wall 30 may be made of materials such as acrylic, polycarbonate, and plexiglass, but is not limited thereto. The retaining wall 30 may be formed by inkjet or coating, but is not limited thereto. In one embodiment, a thickness of the retaining wall 30 is 5-10 microns, but is not limited thereto.

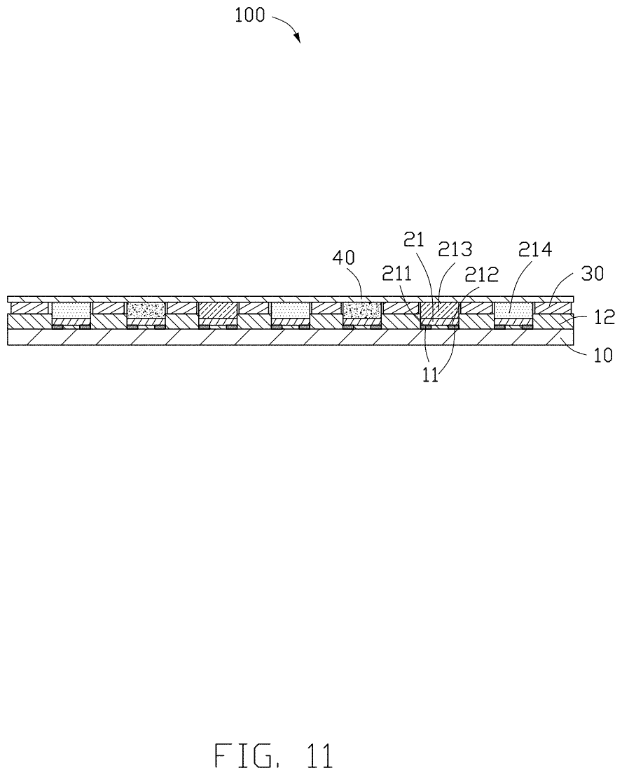

Block S6: As shown in FIG. 10, a color conversion gel 213 and a diffusion gel 214 are individually formed on corresponding light-emitting diodes 21.

In one embodiment, the light-emitting diode 21 is a blue light-emitting diode. After the color conversion gel 213 and the diffusion gel 214 are formed on the corresponding light-emitting diodes 21, a red, green, and blue light array is obtained. In one embodiment, a height of the color conversion gel 213 and a height of the diffusion gel 214 are substantially the same as a height of the retaining wall 30. The height refers to a height calculated from a surface of the array substrate 10 on which the light-emitting diodes 21 are formed.

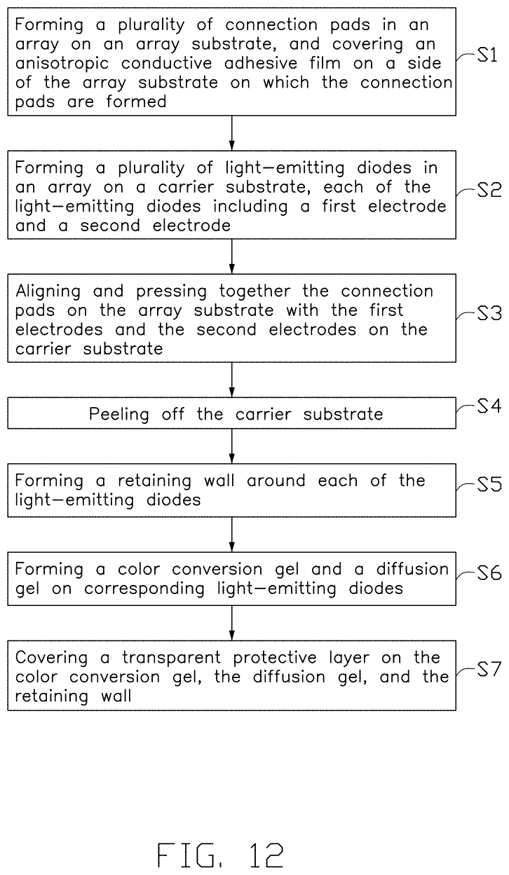

Block S7: As shown in FIG. 11, a transparent protective layer 40 is covered on the color conversion gel 213, the diffusion gel 214, and the retaining wall 30.

The transparent protective layer 40 may be formed by spraying, but is not limited thereto. The transparent protective layer 40 may be made of ultraviolet glue, epoxy resin, or silicone plastic, but is not limited thereto. It can be understood that in some embodiments, block S7 may be omitted.

The method for making the light-emitting diode package structure forms the retaining wall 30 around each of the light-emitting diodes 21 to prevent overlapping light fields between adjacent light-emitting diodes 21 so as to exhibit a point-emission effect, thereby improving a clarity of light output and a reliability of display.

FIG. 11 shows an embodiment of a light-emitting diode package structure 100 made by the above-described method. The light-emitting diode package structure 100 can be used in mobile phones, tablet computers, smart watches, and the like.

The light-emitting diode package structure 100 includes an array substrate 10, light-emitting diodes 21 distributed on the array substrate 10, and a retaining wall 30. The retaining wall 30 isolates each of the light-emitting diodes 21 and prevents overlapping light fields between adjacent light-emitting diodes 21.

Each of the light-emitting diodes 21 includes a first electrode 211 and a second electrode 212. An array of connection pads 11 is formed on the array substrate 10. Each of the first electrodes 211 and each of the second electrodes 212 are connected to a corresponding connection pad 11.

The first electrodes 211 and the second electrodes 212 are connected to the connection pads 11 through an anisotropic conductive adhesive film 12. The anisotropic conductive adhesive film 12 has conductivity in a direction perpendicular to the array substrate 10, and does not have conductivity in a direction parallel to the array substrate 10.

The anisotropic conductive adhesive film 12 is located around each of the light-emitting diodes 21. A thickness of the anisotropic conductive adhesive film 12 is larger than a thickness of the light-emitting diode 21. In one embodiment, the thickness of the anisotropic conductive adhesive film 12 is 10-20 microns.

The retaining wall 30 is located on the anisotropic conductive adhesive film 12 surrounding each of the light-emitting diodes 21. In one embodiment, the retaining wall 30 may be made of acrylic, polycarbonate, or plexiglass, but is not limited thereto. In one embodiment, the retaining wall 30 may be formed by inkjet or coating, but is not limited thereto. In one embodiment, a thickness of the retaining wall 30 is 5-10 microns, but is not limited thereto.

Each of the light-emitting diodes 21 is provided with a color conversion gel 213 or a diffusion gel 214 to obtain a red, green, and blue light array. In one embodiment, heights of the color conversion gel 213 and the diffusion gel 214 are substantially the same as a height of the retaining wall 30. The height refers to a height calculated from a surface of the array substrate 10 on which the light-emitting diode 21 is provided.

The light-emitting diode package structure 100 further includes a transparent protective layer 40 covering the color conversion gel 213, the diffusion gel 214, and the retaining wall 30 to provide moisture resistance, rust prevention, and protection.

The light-emitting diode package structure 100 includes the retaining wall 30 formed around each of the light-emitting diodes 21 to prevent overlapping light fields between adjacent light-emitting diodes 21 so as to exhibit a point-emission effect, thereby improving a clarity of light output and a reliability of display.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A light-emitting diode package structure comprising:
an array substrate;
a plurality of light-emitting diodes arranged in an array on the array substrate; and
a retaining wall arranged on the array substrate isolating each of the plurality of light-emitting diodes.

2. The light-emitting diode package structure of claim 1, wherein:
the light-emitting diode is a micro light-emitting diode or a sub-millimeter light-emitting diode.

3. The light-emitting diode package structure of claim 1, wherein:
each of the plurality of light-emitting diodes comprises a first electrode and a second electrode;
a plurality of connection pads is formed in an array on the array substrate; and
the first electrodes and the second electrodes are correspondingly coupled to the connection pads on the array substrate.

4. The light-emitting diode package structure of claim 3, wherein:
the first electrodes and the second electrodes are coupled to the connection pads through an anisotropic conductive adhesive film.

5. The light-emitting diode package structure of claim 1, wherein:
each of the plurality of light-emitting diodes is surrounded by an anisotropic conductive adhesive film; and
a thickness of the anisotropic conductive adhesive film is greater than a thickness of the plurality of light-emitting diodes.

6. The light-emitting diode package structure of claim 5, wherein:
the retaining wall is arranged on the anisotropic conductive adhesive film surrounding each of the plurality of light-emitting diodes.

7. The light-emitting diode package structure of claim 6, wherein:
a color conversion gel and a diffusion gel are individually formed on corresponding light-emitting diodes.

8. The light-emitting diode package structure of claim 7, wherein:
a height of the color conversion gel and a height of the diffusion gel are the same as a height of the retaining wall.

9. The light-emitting diode package structure of claim 8, further comprising a transparent protective layer covered on the color conversion gel, the diffusion gel, and the retaining wall.

10. A method for manufacturing a light-emitting diode package structure, the method comprising:
forming a plurality of connection pads in an array on an array substrate;
forming a plurality of light-emitting diodes in an array on a carrier substrate, wherein each of the plurality of light-emitting diodes comprises a first electrode and a second electrode corresponding to the connection pads;
aligning the connection pads on the array substrate with the first electrodes and the second electrodes on the carrier substrate and pressing the connection pads to the first electrodes and the second electrodes;
peeling off the carrier substrate; and
forming a retaining wall around each of the plurality of light-emitting diodes.

11. The method of claim 10, wherein after forming the plurality of connection pads in an array on the array substrate, the method further comprises:
covering an anisotropic conductive adhesive film on a side of the array substrate on which the plurality of connection pads is formed; and
the connection pads are coupled to the first electrodes and the second electrodes through the anisotropic conductive adhesive film.

12. The method of claim 11, wherein:
the retaining wall is formed on the anisotropic conductive adhesive film.

13. The method of claim 12, further comprising:
individually forming a color conversion gel and a diffusion gel on corresponding light-emitting diodes to obtain a red, blue, and green light array.

14. The method of claim 13, further comprising:
covering a transparent protective layer on the color conversion gel, the diffusion gel, and the retaining wall.
